(19) United States
(12) Patent Application Publication
(10) Pub. No.: US 2014/0183755 A1
(43) Pub. Date: Jul. 3, 2014

(54) SEMICONDUCTOR PACKAGE AND FABRICATION METHOD THEREOF

(71) Applicant: SILICONWARE PRECISION INDUSTRIES CO., LTD., Taichung (TW)

(72) Inventors: Fu-Tang Huang, Taichung Hsien (TW); Chun-Chi Ke, Taichung Hsien (TW)

(73) Assignee: SILICONWARE PRECISION INDUSTRIES CO., LTD., Taichung (TW)

(21) Appl. No.: 13/872,494

(22) Filed: Apr. 29, 2013

(30) Foreign Application Priority Data
Jan. 3, 2013 (TW) 102100084

(51) Int. Cl. H01L 23/552; H01L 21/58

(52) U.S. Cl. CPC H01L 23/552; H01L 21/58
USPC 257/774; 438/119

(57) ABSTRACT

A semiconductor package is provided, which includes a carrier having a mounting area and at least a grounding pad; a substrate body having opposite first and second surfaces and a plurality of conductive vias each having a first end exposed from the first surface and a second end opposite to the first end, the substrate body being disposed on the mounting area of the carrier through the second surface thereof; a metal layer formed on the first surface of the substrate body and exposing the first ends of the conductive vias; a conductive body electrically connecting the metal layer and the grounding pad; and a semiconductor element disposed on the substrate body and electrically connected to the first ends of the conductive vias, thereby achieving an EMI shielding effect to prevent interference between electromagnetic waves or electrical signals of the substrate body and the semiconductor element.

### BACKGROUND OF THE INVENTION

1. Field of the Invention

The present invention relates to semiconductor packages and fabrication methods thereof, and more particularly, to a semiconductor package with EMI (Electromagnetic Interference) shielding and a fabrication method thereof.

2. Description of Related Art

Along with the development of semiconductor technologies, more and more electronic elements are integrated in a single semiconductor package. At the same time, the semiconductor package is required to have a smaller size to meet the miniaturization requirement of electronic products. Accordingly, 3D packaging technologies are developed to stack a plurality of chips for integration.

To meet the stacking requirement of the chips, TSV (Through Silicon Via) technologies are developed to form through holes in silicon substrates so as to increase processing speed and reduce power losses.

However, if the stacked chips contain some RF chips or communication chips, interference can easily occur between electromagnetic waves or electrical signals of the chips.

Therefore, there is a need to provide a semiconductor package and a fabrication method thereof so as to overcome the above-described drawbacks.

### SUMMARY OF THE INVENTION

In view of the above-described drawbacks, the present invention provides a semiconductor package, which comprises: a carrier having a mounting area and at least a grounding pad; a substrate body disposed on the mounting area of the carrier, wherein the substrate body has opposite first and second surfaces and a plurality of conductive vias each having a first end exposed from the first surface of the substrate body and a second end opposite to the first end, and the substrate body is disposed on the mounting area of the carrier through the second surface thereof; a metal layer formed on the first surface of the substrate body and exposing the first ends of the conductive vias; a conductive body electrically connecting the metal layer and the grounding pad; and a semiconductor element disposed on the first surface of the substrate body and electrically connected to the first ends of the conductive vias.

The present invention further provides a fabrication method of a semiconductor package, which comprises the steps of: providing a substrate body having opposite first and second surfaces and a plurality of conductive vias each having a first end exposed from the first surface of the substrate body and a second end opposite to the first end; forming a metal layer on the first surface of the substrate body, wherein the first ends of the conductive vias are exposed from the metal layer; disposing the substrate body on a carrier through the second surface thereof, wherein the carrier has at least a grounding pad; and disposing a semiconductor element on the first surface of the substrate body and electrically connecting the semiconductor element and the first ends of the conductive vias, and electrically connecting the metal layer and the grounding pad through at least a conductive body.

Therefore, by electrically connecting the metal layer on the first surface of the substrate body and the grounding pad of the carrier through the conductive body, the present invention achieves an EMI shielding effect so as to prevent interference between electromagnetic waves or electrical signals generated by the substrate body and the semiconductor element.

### BRIEF DESCRIPTION OF DRAWINGS

FIGS. 1A to 1K are schematic cross-sectional views showing a semiconductor package and a fabrication method thereof according to a first embodiment of the present invention, wherein FIG. 1H′ is an upper view of FIG. 1H, FIG. 1I′ is an upper view of FIG. 1I′, and FIG. 1J′ shows another embodiment of FIG. 1J;

FIGS. 2A to 2C are schematic cross-sectional views showing a semiconductor package and a fabrication method thereof according to a second embodiment of the present invention.

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modification and variations can be made without departing from the spirit of the present invention. Further, terms such as “end”, “first”, “second” etc. are merely for illustrative purpose and should not be construed to limit the scope of the present invention.

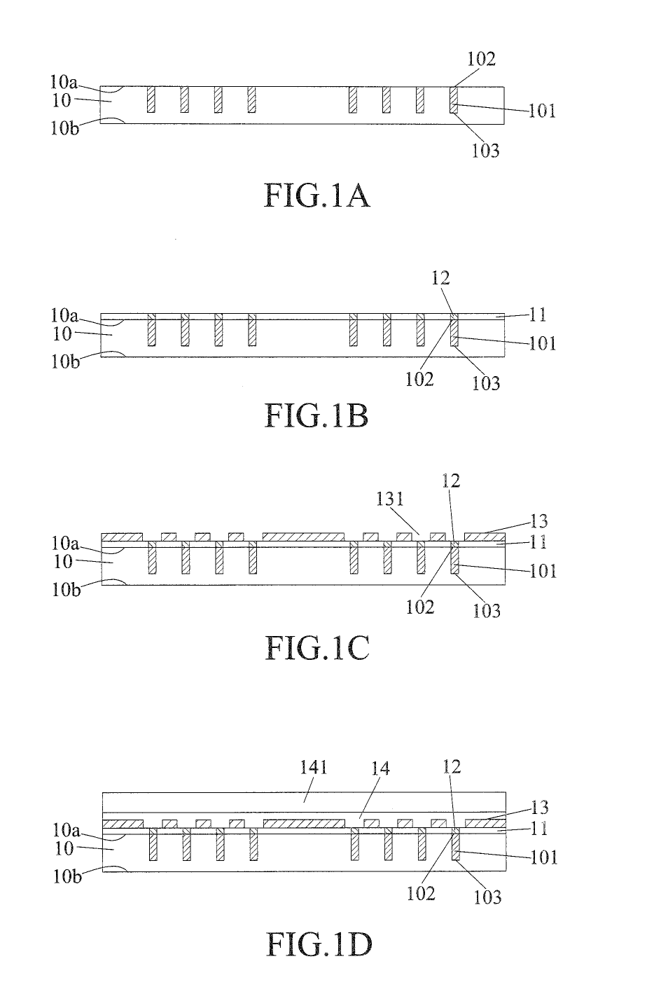

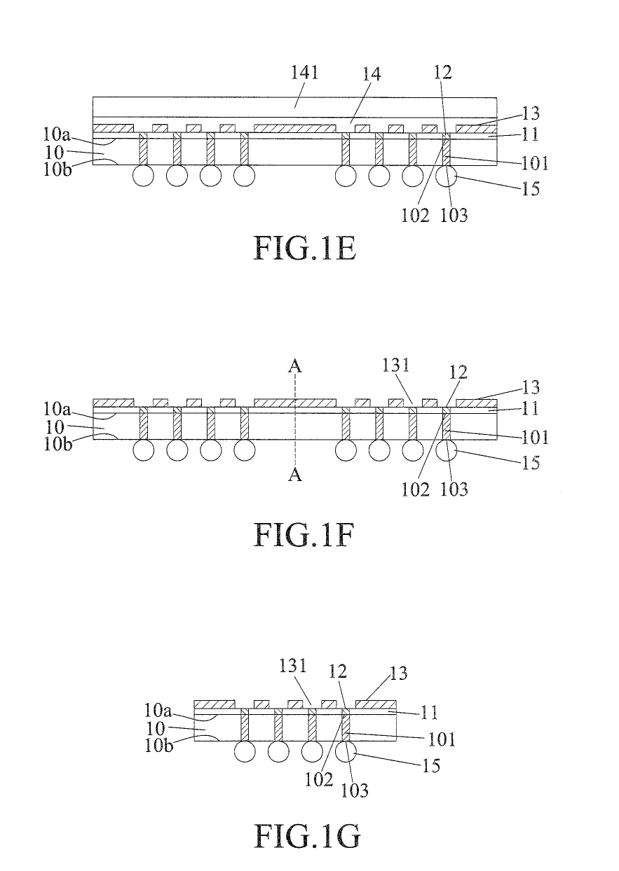

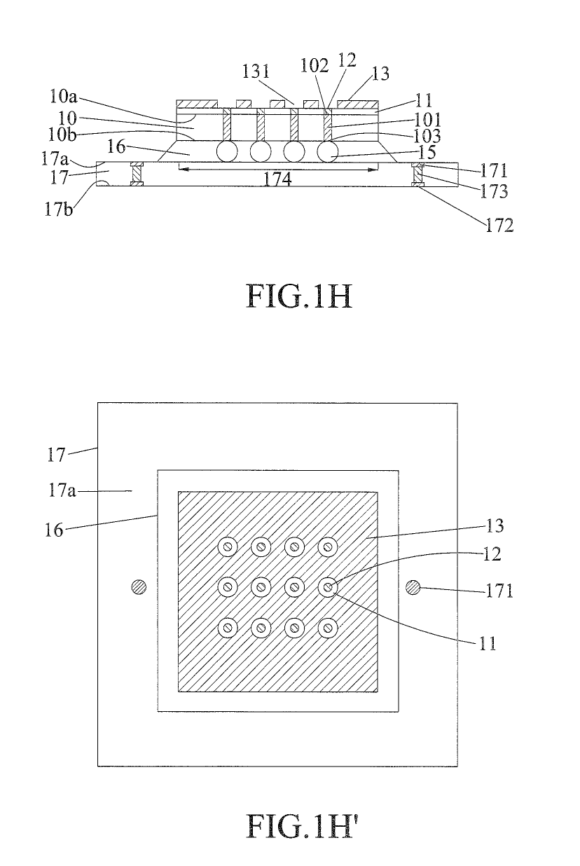

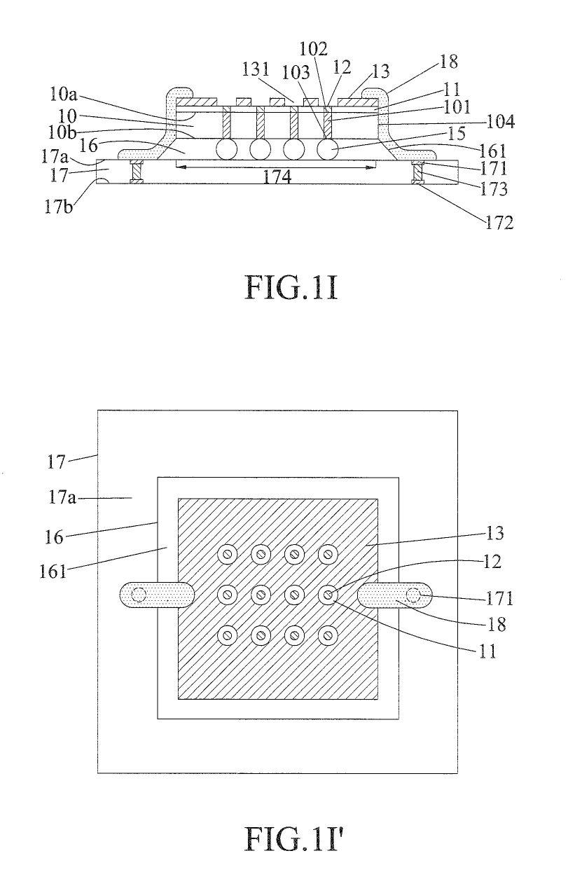

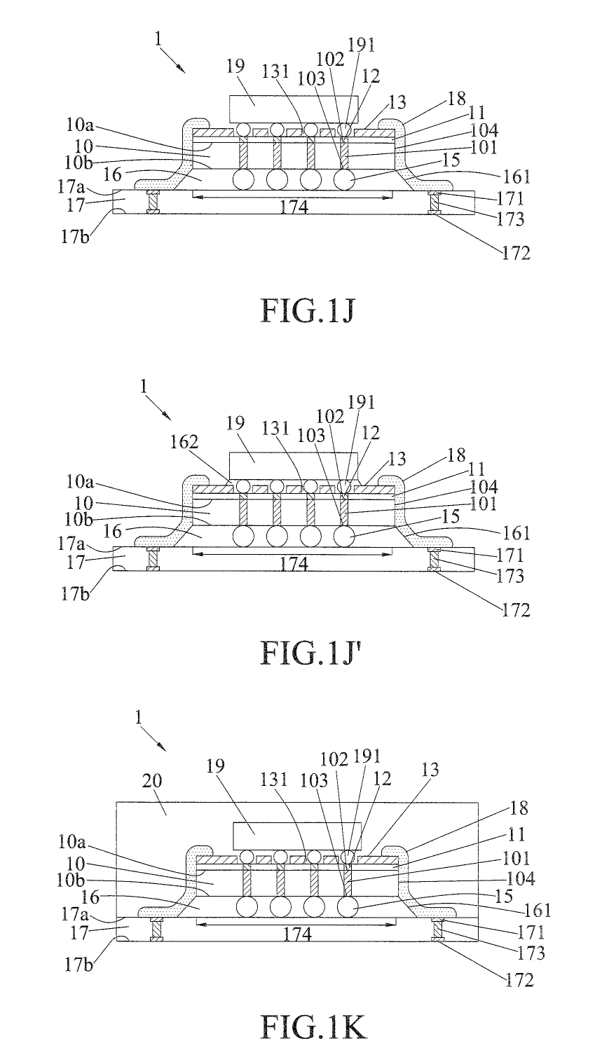

FIGS. 1A to 1K are schematic cross-sectional views showing a semiconductor package and a fabrication method thereof according to a first embodiment of the present invention. Therein, FIG. 1H′ is an upper view of FIG. 1H, FIG. 1I′ is an upper view of FIG II, and FIG. 1J′ shows another embodiment of FIG. 1J.

Referring to FIG. 1A, a substrate body 10 having opposite first and second surfaces 10a, 10b and a plurality of conductive vias 101 is provided. Each of the conductive vias 101 has a first end 102 exposed from the first surface 10a of the substrate body 10 and a second end 103 opposite to first end 102. The conductive vias 101 can be through silicon vias (TSVs) or through holes. The substrate body 10 can be a silicon substrate, an interposer, or a chip having TSVs.

Referring to FIG. 1B, an insulating layer 11 is formed on the first surface 10a of the substrate body 10 and the first ends 102 of the conductive vias 101 are exposed from the insulating layer 11. Further, a conductive material 12 is formed on the first ends 102 of the conductive vias 101. The insulating layer 11 can be a passivation layer. The conductive material 12 can be a metal material.

Referring to FIG. 1C, a metal layer 13 is formed on the insulating layer 11 on the first surface 10a of the substrate body 10, and a plurality of openings 131 are formed in the metal layer 13 for exposing the conductive material 12 on the first ends 102 of the conductive vias 101 and forming a gap between the conductive material 12 and the metal layer 13 to thereby prevent any contact between the conductive material 12 and the metal layer 13. The metal layer 13 can be a copper layer.

Referring to FIG. 1D, an adhesive layer 14 is formed on the metal layer 13 and covers the conductive material 12 and the openings 131 of the metal layer 13. Then, a carrier 141 is disposed on the adhesive layer 14.

Referring to FIG. 1E, the substrate body 10 is thinned from the second surface 10b by grinding, cutting etc. so as to expose the second ends 103 of the conductive vias 101. Thereafter, a plurality of conductive bumps 15 are formed on the second ends 103 of the conductive vias 101, respectively.

Referring to FIG. 1F, the carrier 141 and the adhesive layer 14 are removed to expose the conductive material 12, the metal layer 13 and the openings 131.

Referring to FIG. 1G, the overall structure is cut along a cutting path AA of FIG. 1F so as to obtain a plurality of singulated structure bodies.

Referring to FIGS. 1H and 1H′, the substrate body 10 is disposed on a mounting area 174 of a carrier 17 through the second surface 10b thereof, and the second ends 103 of the conductive vias 101 are electrically connected to the carrier 17 through the conductive bumps 15. Then, an underfill 16 is formed between the second surface 10b of the substrate body 10 and the mounting area 174 of the carrier 17. In another embodiment, an underfill 16 is formed on a top surface 17a of the carrier 17 first and then the substrate body 10 is disposed on the mounting area 174 of the carrier 17 through the second surface 10b thereof and the second ends 103 of the conductive vias 101 are electrically connected to the carrier 17 through the conductive bumps 15.

In the present embodiment, the carrier 17 has a top surface 17a and a bottom surface 17b opposite to the top surface 17a. At least a first grounding pad 171 is formed on the top surface 17a of the carrier 17 and at least a second grounding pad 172 is formed on the bottom surface 17b of the carrier 17, and a conductive through hole 173 is formed in the carrier 17 or penetrates the top and bottom surfaces 17a, 17b of the carrier 17 for electrically connecting the first grounding pad 171 and the second grounding pad 172.

Referring to FIGS. 1I and 1I′, the metal layer 13 and the first grounding pad 171 of the carrier 17 are electrically connected through at least a conductive body 18. The conductive body 18 can be made of a conductive adhesive, which extends from the metal layer 13 along a side surface 104 of the substrate body 10 and a side surface 161 of the underfill 16 to the first grounding pad 171 of the carrier 17.

Referring to FIG. 1J, a plurality of conductive elements 191 are formed on a semiconductor element 19 or the conductive material 12 exposed from the openings 131 of the metal layer 13. Then, the semiconductor element 19 is disposed above the metal layer 13 on the first surface 10a of the substrate body 10 in a flip-chip manner and electrically connected to the conductive material 12 through the conductive elements 191. The conductive elements 19 can be conductive bumps 19. The semiconductor element 19 can be a semiconductor chip, an RF chip or a communication chip.

Referring to FIG. 1J′, an underfill 162 can be formed between the semiconductor element 19 and the metal layer 13 for encapsulating the conductive elements 191 and the openings 131.

Referring to FIG. 1K, continued from FIG. 1J (or FIG. 1J′), an encapsulant 20 is formed on the top surface 17a of the carrier 17 for encapsulating the substrate body 10, the insulating layer 11, the conductive material 12, the metal layer 13, the conductive body 18 and the conductive elements 19.

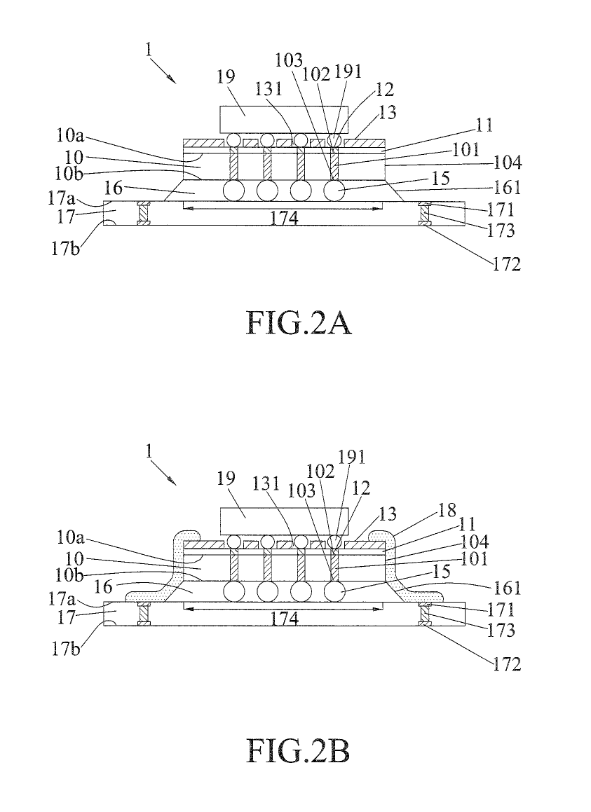

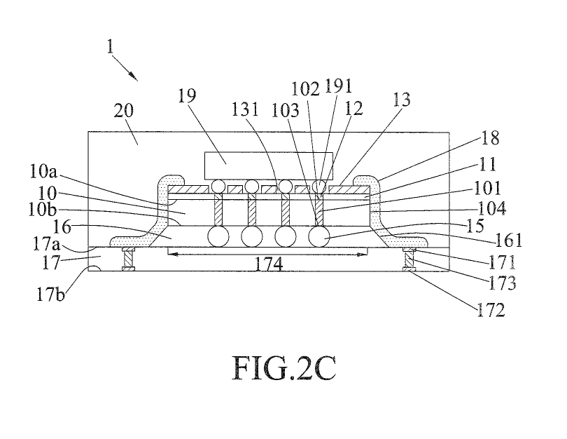

FIGS. 2A to 2C are schematic cross-sectional views showing a semiconductor package and a fabrication method thereof according to a second embodiment of the present invention.

Referring to FIG. 2A, continued from FIG. 1H, a semiconductor element 19 is disposed above the metal layer 13 on the first surface 10a of the substrate body 10 in a flip-chip manner and electrically connected to the conductive material 12 through a plurality of conductive elements 191.

Referring to FIG. 2B, the metal layer 13 and the first grounding pad 171 of the carrier 17 are electrically connected through at least a conductive body 18. The conductive body 18 can be made of a conductive adhesive, which extends from the metal layer 13 along a side surface 104 of the substrate body 10 and a side surface 161 of the underfill 16 to the first grounding pad 171 of the carrier 17.

Referring to FIG. 2C, an encapsulant 20 is formed on the top surface 17a of the carrier 17 for encapsulating the substrate body 10, the insulating layer 11, the conductive material 12, the metal layer 13, the conductive body 18 and the semiconductor element 19.

The present invention further provides a semiconductor package 1. The semiconductor package 1 has a carrier 17. The carrier 17 has a top surface 17a having a mounting area 174 and at least a first grounding pad 171 located outside the mounting area 174, a bottom surface 17b opposite to the top surface 17a and having at least a second grounding pad 172, and at least a conductive through hole 173 electrically connecting the first grounding pad 171 and the second grounding pad 172.

The semiconductor package 1 further has a substrate body 10 disposed on the mounting area 174 of the carrier 17. The substrate body 10 has opposite first and second surfaces 10a, 10b and a plurality of conductive vias 101 each having a first end 102 exposed from the first surface 10a of the substrate body 10 and a second end 103 opposite to the first end 102, and the substrate body 10 is disposed on the mounting area 174 of the carrier 17 through the second surface 10b thereof. The substrate body 10 can be a silicon substrate, an interposer or a chip having TSVs. The conductive vias 101 can be TSVs or through holes.

The semiconductor package 1 further has a metal layer 13 formed on the first surface 10a of the substrate body 10 and exposing the first ends 102 of the conductive vias 101. The metal layer 13 can be a copper layer.

The semiconductor package 1 further has a conductive body 18 electrically connecting the metal layer 13 and the first grounding pad 171 of the carrier 17.

The semiconductor package 1 further has a semiconductor element 19 disposed above the metal layer 13 on the first surface 10a of the substrate body 10 in a flip-chip manner and electrically connected to the first ends 102 of the conductive vias 101. The semiconductor element 19 can be a semiconductor chip, an RF chip or a communication chip.

The semiconductor package 1 further has an encapsulant 20 formed on the top surface 17a of the carrier 17 for encapsulating the substrate body 10, the metal layer 13, the conductive body 18 and the semiconductor element 19.

The semiconductor package 1 further has a conductive material 12 formed on the first ends 102 of the conductive vias 101. The conductive material 12 can be a metal material.

The metal layer 13 has a plurality of openings 131 for exposing the conductive material 12 and forming a gap between the conductive material 12 and the metal layer 13 so as to prevent any contact between the conductive material 12 and the metal layer 13, thereby avoiding grounding of the conductive material 12.

The conductive vias 101 penetrate the first and second surfaces 10a, 10b of the substrate body 10 such that the semiconductor package 1 further has a plurality of conductive bumps 15 formed on the second ends 103 of the conductive vias 101 for electrically connecting the substrate body 10 and the carrier 17.

The semiconductor package 1 further has an underfill 16 formed on the top surface 17a of the carrier 17 for encapsulating the conductive bumps 15.

The conductive body 18 can be made of a conductive adhesive, which extends from the metal layer 13 along a side surface 104 of the substrate body 10 and a side surface 161 of the underfill 16 to the first grounding pad 171 of the carrier 17.

The semiconductor package 1 further has a plurality of conductive elements 191 formed on the semiconductor element 19 or the conductive material 12 for electrically connecting the semiconductor element 19 and the conductive material 12. The conductive elements 191 can be conductive bumps.

Therefore, the present invention involves forming a metal layer such as a copper layer on a first surface of a substrate body; providing a carrier having at least a grounding pad and disposing the substrate body on the carrier through a second surface thereof; and electrically connecting the metal layer on the first surface of the substrate body and the grounding pad of the carrier through a conductive body such as a conductive adhesive. As such, the present invention achieves an EMI shielding effect so as to prevent interference between electromagnetic waves or electrical signals generated by the substrate body such as a chip and a semiconductor element such as an RF chip disposed on the substrate body.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A semiconductor package, comprising:
a carrier having a mounting area and at least a grounding pad;
a substrate body disposed on the mounting area of the carrier, wherein the substrate body has opposite first and second surfaces and a plurality of conductive vias each having a first end exposed from the first surface of the substrate body and a second end opposite to the first end, and the substrate body is disposed on the mounting area of the carrier through the second surface thereof;
a metal layer formed on the first surface of the substrate body and exposing the first ends of the conductive vias;
a conductive body electrically connecting the metal layer and the grounding pad; and
a semiconductor element disposed on the first surface of the substrate body and electrically connected to the first ends of the conductive vias.

2. The package of claim 1, further comprising an insulating layer formed between the first surface of the substrate body and the metal layer and exposing the first ends of the conductive vias.

3. The package of claim 1, further comprising a conductive material formed on the first ends of the conductive vias.

4. The package of claim 3, wherein the metal layer has a plurality of openings for exposing the conductive material and forming a gap between the conductive material and the metal layer.

5. The package of claim 1, wherein the conductive vias penetrate the first and second surfaces of the substrate body and the package further comprises a plurality of conductive bumps respectively formed on the second ends of the conductive vias.

6. The package of claim 1, wherein the conductive body is made of a conductive adhesive, which extends from the metal layer along a side surface of the substrate body to the grounding pad of the carrier.

7. The package of claim 1, wherein the grounding pad is located outside the mounting area.

8. The package of claim 1, further comprising an encapsulant formed on the carrier for encapsulating the substrate body, the metal layer, the conductive body and the semiconductor element.

9. A fabrication method of a semiconductor package, comprising the steps of:
providing a substrate body having opposite first and second surfaces and a plurality of conductive vias each having a first end exposed from the first surface of the substrate body and a second end opposite to the first end;
forming a metal layer on the first surface of the substrate body, wherein the first ends of the conductive vias are exposed from the metal layer;
disposing the substrate body on a carrier through the second surface thereof, wherein the carrier has at least a grounding pad; and
disposing a semiconductor element on the first surface of the substrate body and electrically connecting the semiconductor element and the first ends of the conductive vias, and electrically connecting the metal layer and the grounding pad through at least a conductive body.

10. The method of claim 9, wherein forming the metal layer on the first surface of the substrate body comprises:
forming an insulating layer on the first surface of the substrate body, wherein the first ends of the conductive vias are exposed from the insulating layer;
forming a conductive material on the first ends of the conductive vias; and
forming the metal layer on the insulating layer, wherein the metal layer has a plurality of openings for exposing the conductive material.

11. The method of claim 9, wherein the conductive body is made of a conductive adhesive, which extends from the metal layer along a side surface of the substrate body to the grounding pad of the carrier.

12. The method of claim 9, further comprising thinning the substrate body from the second surface thereof so as to expose the second ends of the conductive vias.

13. The method of claim 9, wherein the metal layer and the grounding pad are electrically connected through the conductive body first and then the semiconductor element is disposed on the first surface of the substrate body and electrically connected to the first ends of the conductive vias.

14. The method of claim 9, wherein the semiconductor element is disposed on the first surface of the substrate body and electrically connected to the first ends of the conductive vias first and then the metal layer and the grounding pad are electrically connected through the conductive body.

15. The method of claim 9, further comprising forming an encapsulant on the carrier for encapsulating the substrate body, the metal layer, the conductive body and the semiconductor element.
